(19) United States
(12) Patent Application Publication
(10) Pub. No.: US 2025/0204217 A1
(43) Pub. Date: Jun. 19, 2025

(54) DISPLAY DEVICE AND METHOD OF MANUFACTURING THE SAME

(71) Applicant: Samsung Display Co., LTD., Yongin-si (KR)

(72) Inventors: Eon Seok OH, Yongin-si (KR); Kwan Hee LEE, Yongin-si (KR)

(21) Appl. No.: 18/795,730

(22) Filed: Aug. 6, 2024

(30) Foreign Application Priority Data
Dec. 15, 2023 (KR) 10-2023-0183179

(51) Int. Cl. H10K 59/80; H10K 59/12; H10K 59/131

(52) U.S. Cl. CPC H10K 59/873; H10K 59/1201; H10K 59/131

(57) ABSTRACT

A display device includes: a substrate including a transmissive area, a display area surrounding the transmissive area, and a middle area between the transmissive area and the display area; a metal layer disposed on the substrate in the middle area to have a closed curve shape surrounding the transmissive area in a plan view; a light emitting film disposed on the substrate to extend from the display area to the middle area; and a common electrode layer disposed to extend from the display area to the middle area and disposed on the light emitting film at least in the display area, where each of the light emitting film and the common electrode layer in the middle area is disposed not to overlap the metal layer in the plan view.

This application claims priority to Korean Patent Application No. 10-2023-0183179, filed on Dec. 15, 2023, and all the benefits accruing therefrom under 35 U.S.C. § 119, the content of which in its entirety is herein incorporated by reference.

### BACKGROUND

### (a) Field

Embodiments of the disclosure relate to a display device and a method of manufacturing the display device.

### (b) Description of the Related Art

A display device includes a display area in which an image is displayed. Recently, research is being conducted on a display device in which various types of components (for example, cameras and the like) are disposed in the display area to increase the area of the display area and add various functions.

### SUMMARY

The disclosure provides a display device in which various types of components are disposed in a display area and a method of manufacturing the display device.

An embodiment of the disclosure provides a display device including: a substrate including a transmissive area, a display area surrounding the transmissive area, and a middle area between the transmissive area and the display area; a metal layer disposed on the substrate in the middle area, where the metal layer has a closed curve shape surrounding the transmissive area in a plan view; a light emitting film disposed on the substrate to extend from the display area to the middle area; and a common electrode layer disposed to extend from the display area to the middle area and disposed on the light emitting film at least in the display area, where each of the light emitting film and the common electrode layer in the middle area is disposed to non-overlap the metal layer in the plan view.

In an embodiment, the display device may further include an encapsulation layer disposed on the common layer to extend from the display area to the middle area and includes a first inorganic encapsulation layer, an organic encapsulation layer, and a second inorganic encapsulation layer which are sequentially stacked therein in at least the display area, where the first inorganic encapsulation layer may be in direct contact with an entire upper surface of the metal layer.

In an embodiment, the first inorganic encapsulation layer and the second inorganic encapsulation layer may be in direct contact with each other in an area in which the metal layer is disposed in the plan view.

In an embodiment, the display device may further include a dam structure disposed in the middle area, where the dam structure has a closed curve shape surrounding the transmissive area in the plan view, and the metal layer may not overlap the dam structure in the plan view.

In an embodiment, the middle area may include a first middle area in which at least one wire bypassing the transmissive area is disposed, and a second middle area surrounded by the first middle area in the plan view, and the metal layer may be disposed in the second middle area.

In an embodiment, the metal layer may include a first metal layer and a second metal layer surrounded by the first metal layer in the plan view.

In an embodiment, at least one stack structure including the light emitting film and the common electrode layer disposed on the light emitting film may be disposed in an area between the first metal layer and the second metal layer in the plan view.

In an embodiment, the display device may further include a pixel electrode disposed below the light emitting film in the display area; a first conductive pattern disposed below the pixel electrode and being in electrical contact with the pixel electrode; and a second conductive pattern disposed below the first conductive pattern and being in electrical contact with the first conductive pattern.

In an embodiment, the metal layer may include a lower metal layer formed of a same material as the second conductive pattern through a same process; and an upper metal layer disposed directly on an upper surface of the lower metal layer and formed of a same material as the first conductive pattern through a same process.

In an embodiment, the display device may further include a capping layer disposed to extend from the display area to the middle area and disposed on the common electrode layer in at least the display area, where the capping layer in the middle area may be disposed not to overlap the metal layer in the plan view.

In an embodiment, a thickness of the metal layer may be about 50 nanometers (nm) or greater.

In an embodiment, the metal layer may include at least one selected from molybdenum and titanium.

Another embodiment of the disclosure provides a method of manufacturing a display device, including: forming a metal layer on a substrate to have a closed curve shape surrounding a transmissive area in a plan view in a middle area of a substrate, where the substrate includes the transmissive area, a display area surrounding the transmissive area, and the middle area between the transmissive area and the display area; forming a light emitting film on the substrate in at least the display area and at least the middle area; forming a common electrode layer on the light emitting film in at least the display area and in at least the middle area; and radiating a laser to the metal layer to remove a portion of each of the light emitting film and the common electrode layer disposed to overlap the metal layer.

In an embodiment, in the radiating the laser, the metal layer may not be removed.

In an embodiment, in the radiating the laser, the laser may be irradiated to the metal layer at least via the substrate.

In an embodiment, in the radiating the laser, an average temperature in the light emitting film overlapping the metal layer may be about 350° C. or higher.

In an embodiment, the radiating the laser may be performed in a vacuum.

In an embodiment, the method of manufacturing the display device may further include forming, after the radiating the laser, an encapsulation layer including a first inorganic encapsulation layer, an organic encapsulation layer, and a second inorganic encapsulation layer which are sequentially stacked therein in at least the display area and at least the middle area, where the first inorganic encapsulation layer may be in direct contact with an entire upper surface of the metal layer.

In an embodiment, the method of manufacturing the display device may further include forming a capping layer on the common electrode layer in at least the display area and in at least the middle area, where in the radiating the laser, the capping layer disposed to overlap the metal layer may be further removed.

In an embodiment, after the radiating the laser, a thickness of the metal layer may be about 50 nm or greater.

In an embodiment, the display device according to embodiments of the disclosure may include a metal layer having a closed curve shape surrounding a transmissive area in a plan view, and each of a light emitting film and a common electrode layer may be disposed not to overlap the metal layer in the plan view. Accordingly, a moisture permeation path defined by the light emitting film and the common electrode layer in an area overlapping the metal layer may be blocked, thereby effectively preventing moisture permeation from the transmissive area to the display area.

In the method of manufacturing the display device according to embodiments of the disclosure, a process of removing the light emitting film and the common electrode layer overlapping the metal layer by radiating a laser to the metal layer having the closed curve shape may be performed. Accordingly, it is possible to provide an efficient manufacturing method to provide a structure for blocking the moisture permeation path.

### BRIEF DESCRIPTION OF THE DRAWINGS

FIG. 1 illustrates a top plan view of a display device according to an embodiment of the disclosure.

FIG. 2 is a circuit diagram showing an embodiment of a pixel included in the display device of FIG. 1.

FIG. 3 is an enlarged view of a transmissive area, a middle area, and a display area according to an embodiment of the disclosure.

FIG. 4 illustrates a cross-sectional view taken along line X1-X1′ of FIG. 3.

FIG. 5 is an enlarged view of a transmissive area, a middle area, and a display area, and is a plan view for explaining a second embodiment of the disclosure.

FIG. 6 illustrates a cross-sectional view taken along line X2-X2′ of FIG. 5.

FIG. 7 is an enlarged view of a transmissive area, a middle area, and a display area according to another embodiment of the disclosure.

FIG. 8 illustrates a cross-sectional view taken along line X3-X3′ of FIG. 7.

FIG. 9 is an enlarged view of a transmissive area, a middle area, and a display area according to another embodiment of the disclosure.

FIG. 10 illustrates a cross-sectional view taken along line X4-X4′ of FIG. 9.

FIG. 11 is a flow chart showing a method of manufacturing a display device according to embodiments of the disclosure.

FIG. 12 to FIG. 15 are cross-sectional views showing processes of an embodiment of the method of manufacturing the display device of FIG. 11.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

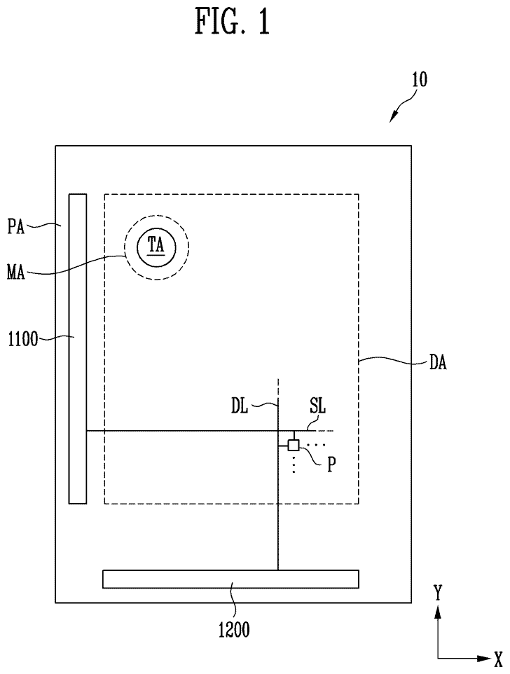

FIG. 1 illustrates a top plan view of a display device according to an embodiment of the disclosure.

Referring to FIG. 1, an embodiment of a display device 10 may include a transmissive area TA, a middle area MA, a display area DA, and a peripheral area PA.

The transmissive area TA may be an area that transmits external light. Components (for example, a camera and the like) having various functions may be disposed in the transmissive area TA. The component may receive external light through the transmissive area TA. In an embodiment, for example, the component may be a camera, and in such an embodiment, the camera may capture an image based on external light received through the transmissive area TA.

An edge of the transmissive area TA may have a shape of a closed curve line in a plan view. In an embodiment, for example, as shown in FIG. 1, the edge of the transmissive area TA may be circular.

In an embodiment of the display device 10, various designs for securing light transmittance in the transmissive area TA may be applied. In an embodiment, for example, a hole may be defined or formed in the transmissive area TA, and the component may be disposed within the hole. In another embodiment, for example, only materials with relatively high light transmittance (for example, an inorganic film, and organic film, or the like) may be disposed in the transmissive area TA.

In an embodiment, an image may be displayed or an image may not be displayed in the transmissive area TA. In an embodiment, where an image is displayed in the transmissive area TA, pixels including, for example, passive organic light emitting diodes may be disposed in the transmissive area TA. Here, the pixels including the passive organic light emitting diodes may be disposed at a density that does not impede light transmittance in the transmissive area TA.

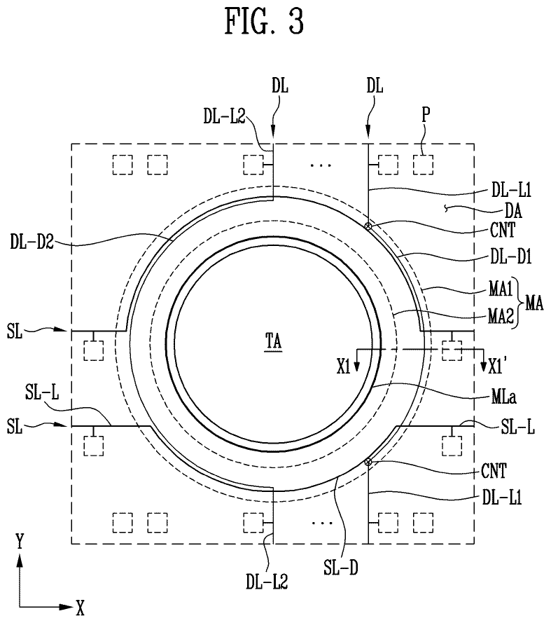

The middle area MA may surround the transmissive area TA. The middle area MA may be an area in which a wire bypassing the transmissive area TA and/or various components for improving the reliability of the display device 10 are disposed. Here, the components disposed in the middle area MA will be described in detail later with reference to FIG. 3 to FIG. 10.

The display area DA may surround the middle area MA. In an embodiment, the display area DA may be an area that displays an image. In such an embodiment, a plurality of pixels P may be disposed in the display area DA. In addition, signal lines that transmit signals to the plurality of pixels P may be disposed in the display area DA. In an embodiment, for example, a scan line SL for transmitting a scan signal to the pixels P, a data line DL for transmitting a data signal to the pixels P, or the like may be disposed in the display area DA.

The peripheral area PA may surround at least one side of the display area DA. Circuit portions for generating the signal provided to the pixels P disposed in the display area DA may be disposed in the peripheral area PA. In an embodiment, for example, in the peripheral area PA, a scan driving circuit portion 1100, which generates the scan signal and is electrically connected to the scan line SL, and a data driving circuit portion 1200, which generates the data signal and is electrically connected to the data line DL, may be disposed.

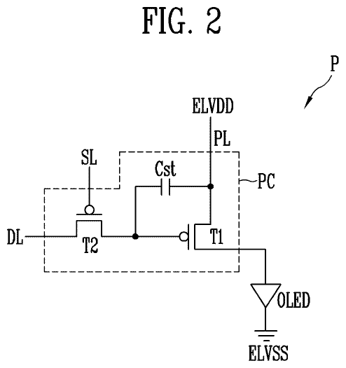

FIG. 2 is a circuit diagram showing an embodiment of a pixel included in the display device of FIG. 1.

Referring to FIG. 2, an embodiment of the pixel PX may include a pixel circuit PC and an organic light emitting diode OLED electrically connected to the pixel circuit PC.

In an embodiment, the pixel circuit PC may include at least one transistor and at least one capacitor. In an embodiment, for example, the pixel circuit PC may include a first transistor T1, a second transistor T2, and a storage capacitor Cst. However, this is an example, and the pixel circuit PC may include a greater number of transistors or a greater number of capacitors.

The second transistor T2 may be connected to the scan line SL and the data line DL to transmit a data signal input from the data line DL to the first transistor T1 based on a scan signal input from the scan line SL.

The storage capacitor Cst may be connected to the second transistor T2 and a driving voltage line PL, and may store a voltage corresponding to a difference between a voltage received from the second transistor T2 and a first power supply voltage ELVDD supplied from the driving voltage line PL.

The first transistor T1 may be connected to the driving voltage line PL and the storage capacitor Cst to control a driving current flowing from the driving voltage line PL to the organic light emitting diode OLED in response to a voltage value stored in the storage capacitor Cst.

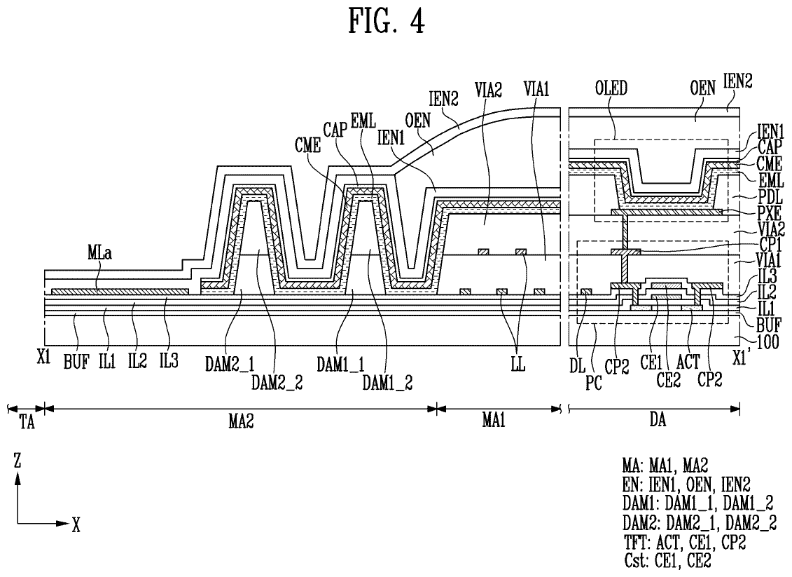

The organic light emitting diode OLED may emit light with a predetermined luminance by the driving current. An opposing electrode (for example, a common electrode layer CME of FIG. 4) of the organic light emitting diode OLED may receive a second power supply voltage ELVSS.

FIG. 3 is an enlarged view of a transmissive area, a middle area, and a display area according to an embodiment of the disclosure.

Referring to FIG. 3, in an embodiment, the middle area MA may be disposed or defined between the transmissive area TA and the display area DA. The middle area MA may include, in a plan view, a second middle area MA2 surrounding the transmissive area TA and a first middle area MA1 surrounding the second middle area MA2.

The pixels P may be disposed in the display area DA to surround the transmissive area TA. Some pixels P may be spaced apart from each other around the transmissive area TA, and the transmissive area TA may be defined between the pixels P. In an embodiment, for example, in a plan view, pixels P may be disposed above and below the transmissive area TA, respectively, and pixels P may be disposed on the left and right sides, respectively.

In an embodiment, among the signal lines that supply signals to the pixels P, signal lines adjacent to the transmissive area TA may bypass the transmissive area TA. In such an embodiment, the signal lines bypassing the transmissive area TA may be disposed in the first middle area MA1.

In an embodiment, as shown in FIG. 3, at least one of the data lines DL passing through the display area DA extends in a Y-direction (i.e., Y-axis direction) to provide a data signal to the pixels P disposed above and below the transmissive area TA, respectively, and may be bypassed along the edge of the transmissive area TA in the first middle area MA1. In addition, at least one of the scan lines SL passing through the display area DA extends in an X-direction (i.e., X-axis direction) to provide a scan signal to the pixels P disposed on the left and right sides of the transmissive area TA, respectively, and may be bypassed along the edge of the transmissive area TA in the first middle area MA1.

A bypass portion SL-D of the scan line SL is disposed in (or directly on) a same layer as an extension portion SL-L crossing the display area DA, and they may be integrally formed with each other as a single unitary indivisible part. A bypass portion DL-D1 of at least one of the data lines DL may be disposed in (or directly on) a different layer from an extension portion DL-L1 crossing the display area DA, and the bypass portion DL-D1 and the extension portion DL-L1 of the data line DL may be connected through a contact hole CNT. A bypass portion DL-D2 of at least one of the data lines DL may be disposed in (or directly on) a same layer as an extension portion DL-L2, and they may be integrally formed with each other as a single unitary indivisible part.

In an embodiment, a metal layer MLa may be disposed in the second middle area MA2. The metal layer MLa may have a closed curve shape surrounding the transmissive area TA in a plan view.

Although not shown in FIG. 3, at least one dam structure may be disposed in the middle area MA. The dam structure may have a closed curve shape surrounding the transmissive area TA in a plan view, and may be disposed not to overlap the metal layer MLa. In an embodiment where a plurality of the dam structures are provided, the dam structures may be disposed to be spaced apart from each other.

FIG. 4 illustrates a cross-sectional view taken along line X1-X1′ of FIG. 3.

Hereinafter, a cross-sectional structure in the display area DA will first be described with reference to FIG. 4.

In an embodiment, the display device 10 may include a substrate 100 including glass and/or a polymer resin. In an embodiment, the substrate 100 may have a multi-layer structure in which a plurality of layers are stacked in a Z-direction (i.e., Z-axis direction) or a thickness direction thereof.

A buffer layer BUF may be disposed on the substrate 100. The buffer layer BUF may serve to prevent impurities from penetrating into a semiconductor layer ACT. The buffer layer BUF may include an inorganic insulating material. In an embodiment, for example, the buffer layer BUF may include a silicon nitride, a silicon oxide, a silicon oxynitride, or the like.

The pixel circuit PC and the organic light-emitting diode OLED may be disposed on the buffer layer BUF. The pixel circuit PC may include a transistor TFT and a storage capacitor Cst.

The transistor TFT may include a semiconductor layer ACT, a first electrode pattern CE1 serving as (or defining) a gate electrode, and a second conductive pattern CP2 serving as a connection electrode. In an embodiment, for example, the transistor TFT may correspond to the first transistor T1 described with reference to FIG. 2. The data line DL of the pixel circuit PC, although not shown in FIG. 4, may be electrically connected to the second transistor T2 included in the pixel circuit PC.

The storage capacitor Cst may include a first electrode pattern CE1 and a second electrode pattern CE2. The first electrode pattern CE1 and second electrode pattern CE2 may correspond to two electrodes of the storage capacitor Cst. In an embodiment, the storage capacitor Cst may overlap the transistor TFT. In an embodiment, for example, the first electrode pattern CE1 may serve as the gate electrode of the transistor TFT and one electrode of the storage capacitor Cst. In another embodiment, the storage capacitor Cst and the transistor TFT may not overlap each other in the Z-direction.

The organic light emitting diode OLED may include a pixel electrode PXE, a common electrode layer CME, and a light emitting film EML interposed between the pixel electrode PXE and the common electrode layer CME. The pixel electrode PXE may be electrically connected to the transistor TFT through a first conductive pattern CP1 included in the pixel circuit PC. The second power supply voltage (ELVSS in FIG. 2) may be applied to the common electrode layer CME.

The semiconductor layer ACT may include a semiconductor material. In an embodiment, for example, the semiconductor layer ACT may include polysilicon, amorphous silicon, an oxide semiconductor, an organic semiconductor, or the like.

The first electrode pattern CE1 may include a low-resistance metallic material. In an embodiment, for example, the first electrode pattern CE1 may include at least one selected from molybdenum, aluminum, copper, and titanium, and may be configured as (or defined by) a multilayer or a single layer including at least one selected from the aforementioned materials.

A first insulating layer IL1 may be disposed between the semiconductor layer ACT and the first electrode pattern CE1. The first insulating layer IL1 may include an inorganic insulating material. In an embodiment, for example, the first insulating layer IL1 may include a silicon nitride, a silicon oxide, a silicon oxynitride, an aluminum oxide, a titanium oxide, a tantalum oxide, a hafnium oxide, or the like, and may be configured as a multilayer or a single layer including at least one selected from the aforementioned materials.

The second electrode pattern CE2 may form the storage capacitor Cst by overlapping the first electrode pattern CE1. The second electrode pattern CE2 may include a low-resistance metallic material. In an embodiment, for example, the second electrode pattern CE2 may include at least one selected from molybdenum, aluminum, copper, and titanium, and may be configured as a multilayer or a single layer including at least one selected from the aforementioned materials.

A second insulating layer IL2 may be disposed between the first electrode pattern CE1 and the second electrode pattern CE2. The second insulating layer IL2 may include an inorganic insulating material. In an embodiment, for example, the second insulating layer IL2 may include a silicon nitride, a silicon oxide, a silicon oxynitride, an aluminum oxide, a titanium oxide, a tantalum oxide, a hafnium oxide, or the like, and may be configured as a multilayer or a single layer including at least one selected from the aforementioned materials.

A third insulating layer IL3 may be disposed on the second insulating layer IL2 and cover the storage capacitor Cst. The third insulating layer IL3 may include an inorganic insulating material. In an embodiment, for example, the third insulating layer IL3 may include a silicon nitride, a silicon oxide, a silicon oxynitride, an aluminum oxide, a titanium oxide, a tantalum oxide, a hafnium oxide, or the like, and may be configured as a multilayer or a single layer including at least one selected from the aforementioned materials.

The second conductive pattern CP2 may be disposed on the third insulating layer IL3. The second conductive pattern CP2 may be connected to the semiconductor layer ACT through a through-hole defined or formed in the first to third insulating layers IL1, IL2, and IL3. In an embodiment, the second conductive pattern CP2 may be disposed in (or direct on) a same layer as the data line DL. That is, the second conductive pattern CP2 may be formed of a same material as the data line DL through a same process. The second conductive pattern CP2 and the data line DL may include materials with high conductivity. In an embodiment, for example, the second conductive pattern CP2 and the data line DL may include molybdenum, aluminum, copper, or titanium, and may be configured as a multilayer or a single layer including at least one selected from the above-mentioned materials.

The first conductive pattern CP1 may be disposed on a first via insulating layer VIA1. The first conductive pattern CP1 may be connected to the second conductive pattern CP2 through a through-hole defined or formed in the first via insulating layer VIA1. The first conductive pattern CP1 may serve to electrically connect the transistor TFT and the pixel electrode PXE to each other. The first conductive pattern CP1 may include a material with high conductivity. In an embodiment, for example, the first conductive pattern CP1 may include molybdenum, aluminum, copper, or titanium, and may be configured of a multilayer or a single layer including at least one selected from the above-mentioned materials.

The pixel electrode PXE may be disposed on a second via insulating layer VIA2. The pixel electrode PXE may be in contact with the first conductive pattern CP1 through a through-hole defined or formed in the second via insulating layer VIA2. In an embodiment, the pixel electrode PXE may include a conductive oxide. In an embodiment, for example, the pixel electrode PXE may include at least one selected from an indium tin oxide (ITO), an indium zinc oxide (IZO), a zinc oxide (ZnO), an indium oxide (In₂O₃), an indium gallium oxide (IGO), and an aluminum zinc oxide (AZO). In another embodiment, the pixel electrode PXE may include a metallic material. In an embodiment, for example, the pixel electrode PXE may include silver, magnesium, aluminum, platinum, palladium, gold, nickel, neodymium, iridium, chromium, or the like. In another configuration, the pixel electrode PXE may have a multilayer structure including the above-mentioned conductive oxide and/or metallic material.

The first via insulating layer VIA1 and the second via insulating layer VIA2 may include an organic insulating material. In an embodiment, for example, the first via insulating layer VIA1 and the second via insulating layer VIA2 may include PMMA, polystyrene, a polymer derivative having a phenol group, an acrylic polymer, an imide polymer, an amide polymer, a fluorine-based polymer, or a vinyl alcohol-based polymer.

The pixel defining film PDL may be disposed on the pixel electrode PXE. The pixel defining film PDL may expose the upper surface of the pixel electrode PXE, and may protrude along the circumference of the pixel. The pixel defining film PDL may serve to partition a light emitting area of each pixel. The pixel defining film PDL may include an organic insulating material. Alternatively, the pixel defining film PDL may include an inorganic insulating material. Alternatively, the pixel defining film PDL may have a multi-layer structure including an organic insulating material and/or an inorganic insulating material.

The light emitting film EML may be disposed in a pixel area surrounded by the pixel defining film PDL. The light emitting film EML may include a low-molecular or high-molecular material. In an embodiment, for example, the light emitting film EML may include copper phthalocyanine (CuPc), N,N′-Di(naphthalene-1-yl)-N,N′-diphenyl-benzidine (NPB), tris-8-hydroxyquinoline aluminum)(Alq3), PEDOT, a poly-phenylenevinylene (PPV) compound, or a polyfluorene compound.

The light emitting film EML may be provided as a single layer, or may also be provided as a multilayer including various functional layers. In an embodiment where the light emitting film EML is provided as a multilayer, the light emitting film EML may have a structure in which a hole injection layer (HIL), a hole transport layer (HTL), an emission layer (EL), an electron transport layer (ETL), an electron injection layer (EIL) are stacked in a single or complex structure.

In some embodiments, at least a portion of the light emitting film EML may be integrally or commonly formed across the plurality of pixel electrodes PXE, or may be individually provided to correspond to each of the plurality of pixel electrodes PXE.

The common electrode layer CME may be disposed on the light emitting film EML. The common electrode layer CME may be disposed for each pixel, but may be disposed to cover most of the display area DA and may be shared by a plurality of pixels.

The common electrode layer CME may include a metallic material and/or a transparent conductive material. In an embodiment, for example, the common electrode layer CME may include silver, magnesium, aluminum, platinum, palladium, gold, nickel, neodymium, iridium, chromium, an indium tin oxide (ITO), an indium zinc oxide (ZO), a zinc oxide (ZnO), an indium tin oxide (ITZO), or the like.

A capping layer CAP may be disposed on the common electrode layer CME. The capping layer CAP may serve to improve light emission efficiency of the organic light emitting diode OLED. The capping layer CAP may include, for example, an organic material or an inorganic material (for example, LiF).

An encapsulation layer EN may entirely cover the organic light emitting diode OLED. The encapsulation layer EN may serve to protect the organic light-emitting diode OLED from external moisture and gas. The encapsulation layer EN may include a first inorganic encapsulation layer IEN1, a second inorganic encapsulation layer IEN2, and an organic encapsulation layer OEN interposed between the first inorganic encapsulation layer IEN1 and the second inorganic encapsulation layer IEN2. The first inorganic encapsulation layer IEN1 and the second inorganic encapsulation layer IEN2 may include an inorganic insulating material, and the organic encapsulation layer OEN may include an organic insulating material.

Hereinafter, a cross-sectional structure in the middle area MA will be described with reference to FIG. 4.

The buffer layer BUF, the first insulating layer IL1, the second insulating layer IL2, and the third insulating layer IL3 may extend from the display area DA and may also be disposed in the middle area MA.

The first via insulating layer VIA1 and the second via insulating layer VIA2 may extend from the display area DA and may also be disposed in the first middle area MA1.

In the first middle area MA1, signal lines LL bypassing the transmissive area TA may be disposed between the first via insulating layer VIA1 and the third insulating layer IL3, and between the first via insulating layer VIA1 and the second via insulating layer VIA2. Each of the signal lines LL may correspond to one of the extension portion DL-L of the data line DL, the bypass portions DL-D1 and DL-D2 of the data line DL, the extension portion SL-L of the scan line SL, and the bypass portion SL-D of the scan line SL described with reference to FIG. 3.

A dam structure may be disposed in the second middle area MA2. In an embodiment, for example, the dam structure may include a first dam structure DAM1 and a second dam structure DAM2. The first dam structure DAM1 may have a closed curve shape surrounding the transmissive area TA in a plan view (when viewed in the Z-direction), and the second dam structure DAM2 may have a closed curve shape surrounding the transmissive area TA between the first dam structure DAM1 and the transmissive area TA in a plan view.

In an embodiment, the first dam structure DAM1 may include a first first dam structure DAM1-1 and a second first dam structure DAM1-2 disposed on the first first dam structure DAM1-1. Here, the first first dam structure DAM1-1 and the second first dam structure DAM1-2 may be formed of a same material as at least two organic insulating layers selected from the first via insulating layer VIA1, the second via insulating layer VIA2, and the pixel defining film PDL through a same process.

In an embodiment, the second dam structure DAM2 may include a first second dam structure DAM2-1 and a second second dam structure DAM2-2 disposed on the first second dam structure DAM2-1. Here, the first second dam structure DAM2-1 and the second second dam structure DAM2-2 may be formed of a same material as at least two organic insulating layers selected the first via insulating layer VIA1, the second via insulating layer VIA2, and the pixel defining film PDL through a same process.

The metal layer MLa may be disposed in the second middle area MA2. The metal layer MLa may be disposed on the third insulating layer IL3. The metal layer MLa may be disposed not to overlap the first and second dam structures DAM1 and DAM2 in a plan view or in the Z-direction. In an embodiment, for example, the metal layer MLa may be disposed between the second dam structure DAM2 and the transmissive area TA.

The metal layer MLa may be formed of a same material as the first conductive pattern CP1 through a same process. In another embodiment, the metal layer MLa may be formed of a same material as the second conductive pattern CP2 through a same process.

The light emitting film EML, the common electrode layer CME, and the capping layer CAP may be disposed to extend from the display area DA to the middle area MA. In an embodiment, for example, the light emitting film EML, the common electrode layer CME, and the capping layer CAP may extend from the display area DA to entirely cover the second dam structure DAM2. In such an embodiment, the light emitting film EML, the common electrode layer CME, and the capping layer CAP may be disposed not to overlap the metal layer MLa.

The encapsulation layer EN may be disposed to extend from the display area DA to the middle area MA. Here, the organic encapsulation layer OEN of the encapsulation layer EN may be blocked by the first dam structure DMA1. Accordingly, the first inorganic encapsulation layer IEN1 and the second inorganic encapsulation layer IEN2 may directly contact each other at a position from above the first dam structure DAM1.

The first inorganic encapsulation layer IEN1 may directly contact the entire upper surface of the metal layer MLa. The metal layer MLa may be directly covered entirely by the first inorganic encapsulation layer IEN1. In an embodiment, in an area in which the metal layer MLa is disposed, the first inorganic encapsulation layer IEN1 and the second inorganic encapsulation layer IEN2 may directly contact each other.

Hereinafter, a cross-sectional structure in the transmissive area TA will be described with reference to FIG. 4.

In the transmissive area TA, a hole may be defined in the substrate 100. In addition, the aforementioned components (for example, BUF, IL1, and the like) may not be disposed in an area overlapping the hole.

In an embodiment, although not shown in FIG. 4, components having various functions (for example, a camera and the like) may be disposed in the transmissive area TA.

Referring back to FIG. 3 and FIG. 4, in an embodiment of the disclosure, the metal layer MLa with a closed curve shape surrounding the transmissive area TA may be disposed in the middle area MA in a plan view. In addition, in the middle area MA, the light emitting film EML, the common electrode layer CME, and the capping layer CAP may be disposed not to overlap the metal layer MLa in the plan view. Accordingly, a moisture permeable path defined by the light emitting film EML, the common electrode layer CME, and the capping layer CAP may be blocked between the transmissive area TA and the display area DA. That is, each of the light emitting film EML, the common electrode layer CME, and the capping layer CAP may not be continuously disposed from the transmissive area TA to the display area DA without disconnection.

In such an embodiment, as described above, as the moisture permeation path is blocked in the area in which the metal layer MLa is disposed, the reliability of the display device 10 may be improved.

In an embodiment, the thickness of the metal layer MLa in the Z-direction may be about 50 nanometers (nm) or greater. When the thickness of the metal layer MLa satisfies the above-mentioned numerical range, it is possible to effectively suppress further formation of a moisture permeable path through the metal layer MLa in addition to the moisture permeable path defined by the light emitting film EML, the common electrode layer CME, and the capping layer CAP described above.

In an embodiment, the metal layer MLa may include at least one selected from molybdenum and titanium.

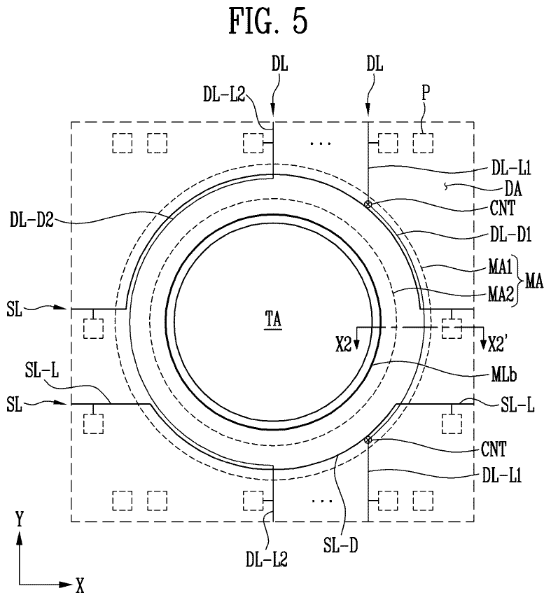

FIG. 5 is an enlarged view of a transmissive area, a middle area, and a display area according to another embodiment of the disclosure. The same or like elements shown in FIG. 5 have been labeled with the same reference characters as used above to describe the embodiment shown in FIG. 3, and any repetitive detailed description thereof will be omitted.

Referring to FIG. 5, a metal layer MLb may be disposed in the second middle area MA2. The metal layer MLb may have a closed curve shape surrounding the transmissive area TA in a plan view.

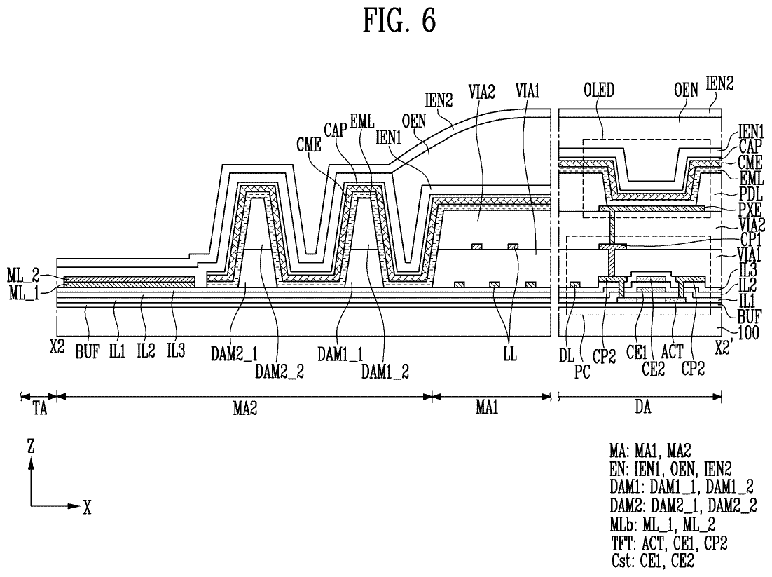

FIG. 6 illustrates a cross-sectional view taken along line X2-X2′ of FIG. 5. The same or like elements shown in FIG. 6 have been labeled with the same reference characters as used above to describe the embodiment shown in FIG. 4, and any repetitive detailed description thereof will be omitted.

Referring to FIG. 6, in an embodiment, the metal layer MLb may include a lower metal layer ML_1 and an upper metal layer ML_2.

The lower metal layer ML_1 may be formed of a same material as the second conductive pattern CP2 through a same process.

The upper metal layer ML_2 may be directly disposed on the upper surface of the lower metal layer ML1. The upper metal layer ML_2 may be formed of a same material as the first conductive pattern CP1 through a same process.

In such an embodiment, as shown in FIG. 6, the metal layer MLb may have a stacked structure of the lower metal layer ML_1 and the upper metal layer ML_2. Accordingly, the thickness of the metal layer MLb of the embodiment shown in FIG. 6 in the Z-direction may be greater than the thickness of the metal layer MLa of the embodiment shown in FIG. 4 in the Z-direction. That is, the thickness of the metal layer MLb may be relatively large, and accordingly, it is possible to more effectively suppress the formation of the moisture permeable path through the metal layer MLa.

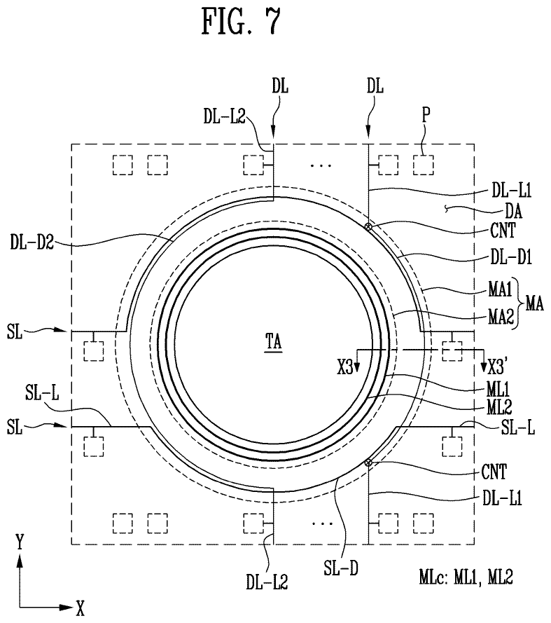

FIG. 7 is an enlarged view of a transmissive area, a middle area, and a display area according to another embodiment of the disclosure. The same or like elements shown in FIG. 7 have been labeled with the same reference characters as used above to describe the embodiment shown in FIG. 3, and any repetitive detailed description thereof will be omitted.

Referring to FIG. 7, in an embodiment, a metal layer MLc may be disposed in the second middle area MA2. The metal layer MLc may include a first metal layer ML1 and a second metal layer ML2.

The first metal layer ML1 may have a closed curve shape surrounding the second metal layer ML2. The second metal layer ML2 may have a closed curve shape surrounding the transmissive area TA.

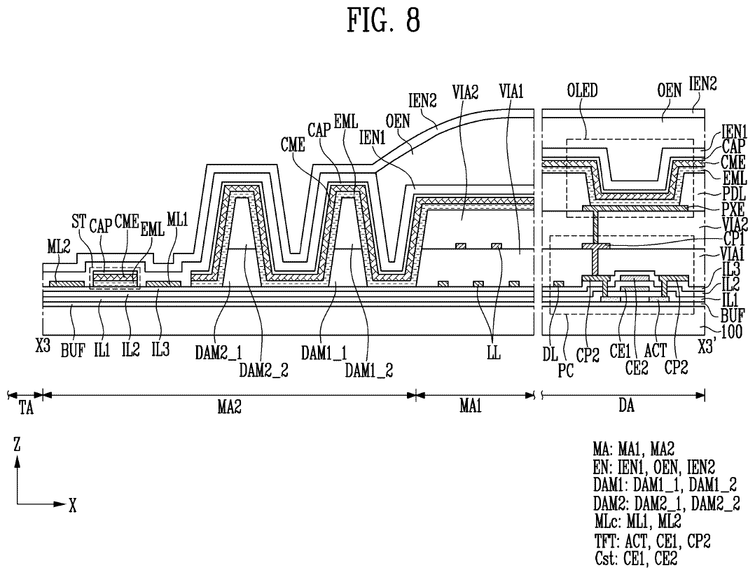

FIG. 8 illustrates a cross-sectional view taken along line X3-X3′ of FIG. 7. The same or like elements shown in FIG. 8 have been labeled with the same reference characters as used above to describe the embodiment shown in FIG. 4, and any repetitive detailed description thereof will be omitted.

Referring to FIG. 8, in an embodiment, the light emitting film EML, the common electrode layer CME, and the capping layer CAP may be disposed not to overlap the first metal layer ML1 and the second metal layer ML2. In such an embodiment, in a separation area between the first metal layer ML1 and the second metal layer ML2, a stacked structure ST including the light emitting film EML, the common electrode layer CME, and the capping layer CAP, which are sequentially stacked, may be disposed.

In some embodiments, at least one selected from the first metal layer ML1 and the second metal layer ML2 may have a double layer structure as in the metal layer MLb described with reference to FIG. 6.

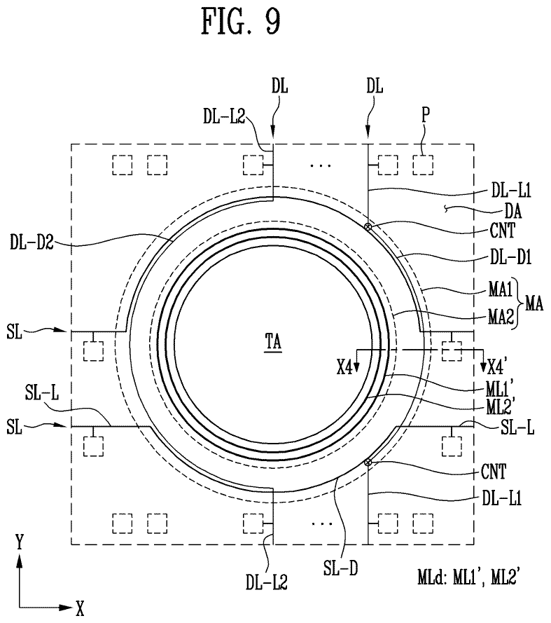

FIG. 9 is an enlarged view of a transmissive area, a middle area, and a display area, and is a plan view for explaining a fourth embodiment of the disclosure. The same or like elements shown in FIG. 9 have been labeled with the same reference characters as used above to describe the embodiment shown in FIGS. 3 and 7, and any repetitive detailed description thereof will be omitted.

Referring to FIG. 9, in an embodiment, a metal layer MLd may be disposed in the second middle area MA2. The metal layer MLd may include a first metal layer ML1′ and a second metal layer ML2′.

The first metal layer ML1′ may have a closed curve shape surrounding the second metal layer ML2′. The second metal layer ML2′ may have a closed curve shape surrounding the transmissive area TA.

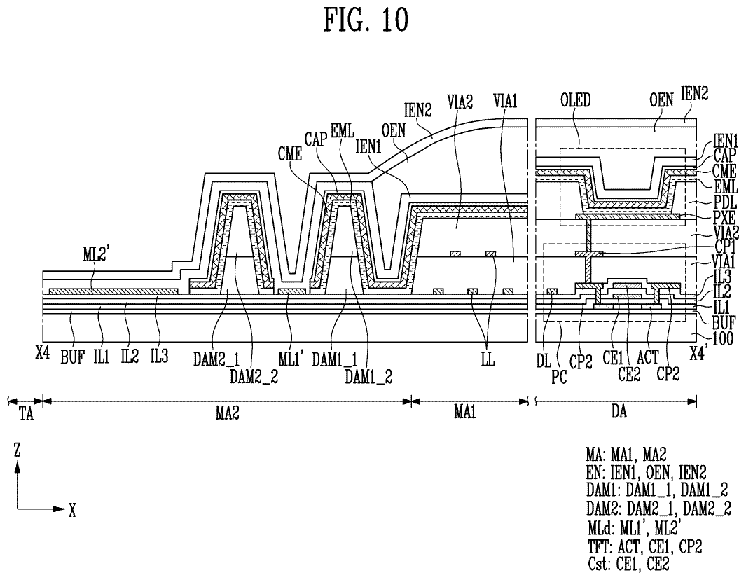

FIG. 10 illustrates a cross-sectional view taken along line X4-X4′ of FIG. 9. The same or like elements shown in FIG. 10 have been labeled with the same reference characters as used above to describe the embodiment shown in FIGS. 3 and 8, and any repetitive detailed description thereof will be omitted.

Referring to FIG. 10, the first metal layer ML1′ may be disposed between the first dam structure DAM1 and the second dam structure DAM2, and the second metal layer ML2′ may be disposed between the second dam structure DAM2 and the transmissive area TA.

In embodiments, as described above, the metal layer MLd may include various metal layers disposed in various areas within the second middle area MA2. In such embodiments, various metal layers included in the metal layer MLd may have a closed curve shape surrounding the transmissive area TA while being spaced apart from each other, and may be disposed to non-overlap the dam structure. In an embodiment, for example, the metal layer MLd may further include a metal layer disposed between the first dam structure DAM1 and the first middle area MA1. In addition, the metal layer MLd may include three or more metal layers that satisfy the above-mentioned conditions.

in an embodiment, at least one selected from the metal layers included in the metal layer MLd may have a double layer structure as in the metal layer MLb described with reference to FIG. 6.

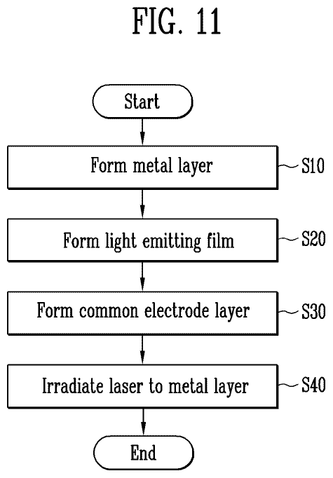

FIG. 11 is a flow chart showing a method of manufacturing a display device according to embodiments of the disclosure.

Referring to FIG. 11, an embodiment of the method of manufacturing the display device 10 may include forming a metal layer (S10), forming a light emitting film (S20), forming a common electrode layer (S30), and radiating a laser to the metal layer (S40).

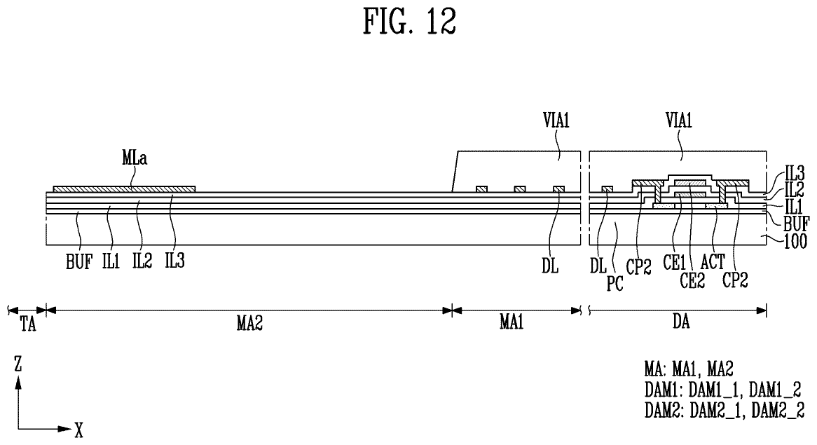

FIG. 12 to FIG. 15 are cross-sectional views showing processes of an embodiment of the method of manufacturing the display device of FIG. 11. The same or like elements shown in FIG. 12 to FIG. 15 have been labeled with the same reference characters as used above to describe the embodiment shown in FIGS. 3 and 4 and any repetitive detailed description thereof will be omitted.

Referring to FIG. 12, the metal layer MLa may be formed on the substrate 100 (S10). In an embodiment, the metal layer MLa may be formed of a same material as the second conductive pattern CP2 through a same process. In another embodiment, the metal layer MLa may be formed of a same material as the first conductive pattern (CP1 in FIG. 3) through a same process.

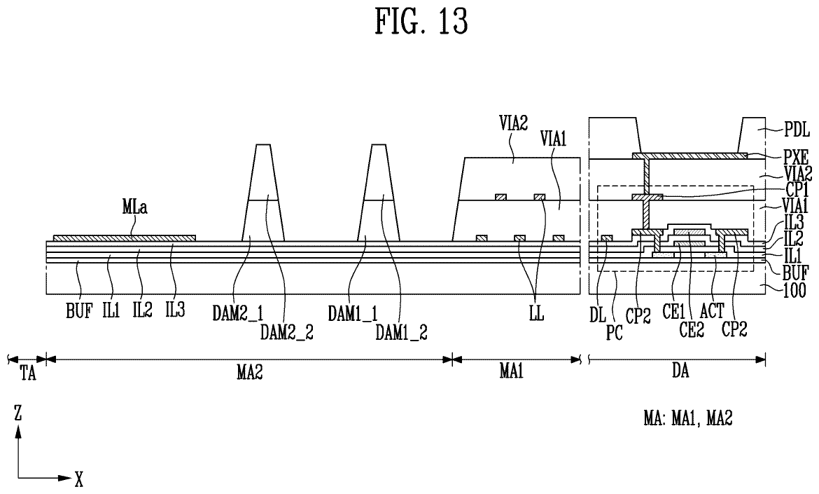

Referring to FIG. 13, the first dam structure DAM1, the second dam structure DAM2, the signal lines LL, the pixel circuit PC, the pixel electrode PXE, and the pixel defining film PDL may be formed on the substrate 100. There is no limitation to the method of forming the above-described components, and they may be formed by applying a suitable formation method known in the art according to the stacking order thereof.

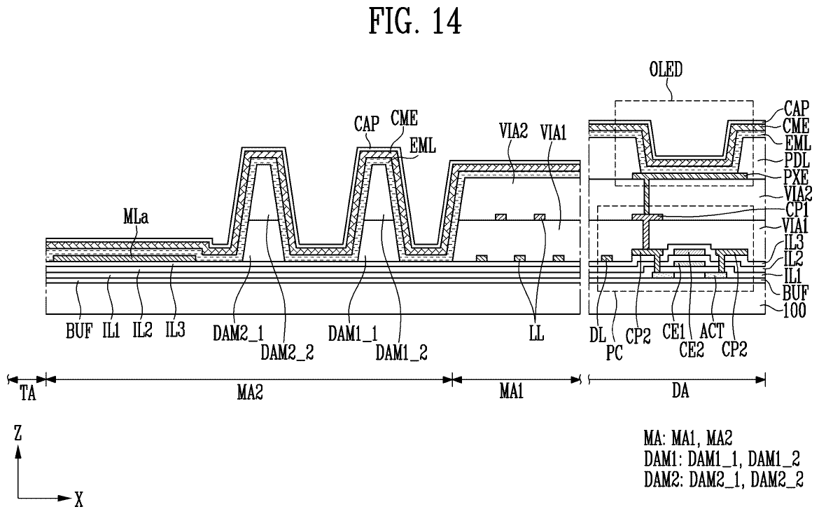

Referring to FIG. 14, the light emitting film EML may be formed over the substrate 100 (S20), the common electrode layer CME may be formed over the substrate 100 (S30), and the capping layer CAP may be formed over the substrate 100. In such an embodiment, the light emitting film EML, the common electrode layer CME, and the capping layer CAP may be entirely formed in at least the display area DA and at least the middle area MA.

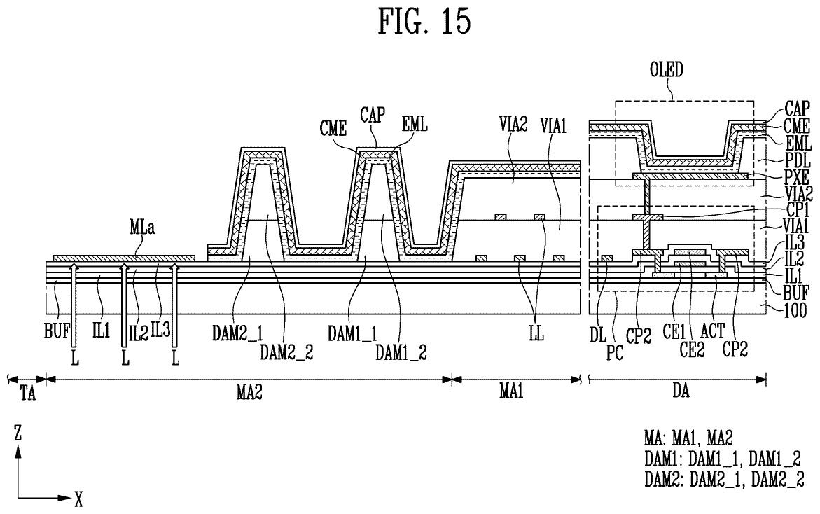

Referring to FIG. 15, the light emitting film EML, the common electrode layer CME, and the capping layer CAP disposed to overlap the metal layer MLa may be removed by irradiating the metal layer MLa with a laser L (S40). In such an embodiment, the metal layer MLa may not be substantially removed by the laser L. In an embodiment, for example, after radiation of the laser L, the thickness of the metal layer MLa may be about 50 nm or more.

As the laser L, various types of lasers may be used to sufficiently increase the temperature of the metal layer MLa so that the light emitting film EML, the common electrode layer CME, and the capping layer CAP disposed to overlap the metal layer MLa may be removed. In an embodiment, for example, the laser L may be a laser in the form of a Gaussian beam.

The laser L may be radiated for a relatively short time. For example, the laser L may be radiated with an intensity of about 200 millijoules per square centimeter (mJ/cm²) to about 500 mJ/cm² for 2 nanoseconds (ns) to 14 ns. When the radiation time of the laser L is increased, the process efficiency may decrease and the yield of the display device 10 may decrease.

The temperature of the metal layer MLa may increase due to the radiation of the laser L, and accordingly, the light emitting film EML, the common electrode layer CME, and the capping layer CAP disposed to overlap the metal layer MLa may be decomposed. In an embodiment, the metal layer MLa may include a material that may cause a sufficient temperature to increase even when the laser L is radiated for a relatively short time as described above. In an embodiment, for example, the metal layer MLa may include at least one selected from molybdenum and titanium. Accordingly, when the laser L is radiated, the average temperature in the light emitting film EML overlapping the metal layer MLa may be about 350° C. or higher.

When the laser L is radiated, the laser L may be radiated to the metal layer MLa via at least the substrate 100. That is, the laser L may be radiated in a direction of a rear surface of the substrate 100.

In an embodiment, the radiation of the laser L may be performed in a vacuum. Accordingly, the light emitting film EML, the common electrode layer CME, and the capping layer CAP may be efficiently decomposed and removed.

In an embodiment, after radiating the laser L, the encapsulation layer EN may be formed in at least the display area DA and at least the middle area MA.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a transmissive area, a display area surrounding the transmissive area, and a middle area between the transmissive area and the display area;
a metal layer disposed on the substrate in the middle area, wherein the metal layer has a closed curve shape surrounding the transmissive area in a plan view;
a light emitting film disposed on the substrate to extend from the display area to the middle area; and
a common electrode layer disposed to extend from the display area to the middle area and disposed on the light emitting film at least in the display area,
wherein each of the light emitting film and the common electrode layer in the middle area is disposed not to overlap the metal layer in the plan view.

2. The display device of claim 1, further comprising
an encapsulation layer disposed on the common electrode layer to extend from the display area to the middle area, wherein the encapsulation layer includes a first inorganic encapsulation layer, an organic encapsulation layer, and a second inorganic encapsulation layer which are sequentially stacked therein in at least the display area,
wherein the first inorganic encapsulation layer is in direct contact with an entire upper surface of the metal layer.

3. The display device of claim 2, wherein
the first inorganic encapsulation layer and the second inorganic encapsulation layer are in direct contact with each other in an area in which the metal layer is disposed in the plan view.

4. The display device of claim 1, further comprising
a dam structure disposed in the middle area, wherein the dam structure has a closed curve shape surrounding the transmissive area in the plan view,
wherein the metal layer does not overlap the dam structure in the plan view.

5. The display device of claim 1, wherein
the middle area includes a first middle area in which at least one wire bypassing the transmissive area is disposed, and a second middle area surrounded by the first middle area in the plan view, and
the metal layer is disposed in the second middle area.

6. The display device of claim 1, wherein
the metal layer includes a first metal layer and a second metal layer surrounded by the first metal layer in the plan view.

7. The display device of claim 6, wherein
at least one stack structure including the light emitting film and the common electrode layer disposed on the light emitting film is disposed in an area between the first metal layer and the second metal layer in the plan view.

8. The display device of claim 1, further comprising
a pixel electrode disposed below the light emitting film in the display area;
a first conductive pattern disposed below the pixel electrode and being in electrical contact with the pixel electrode; and
a second conductive pattern disposed below the first conductive pattern and being in electrical contact with the first conductive pattern.

9. The display device of claim 8, wherein
the metal layer includes
a lower metal layer formed of a same material as the second conductive pattern through a same process; and
an upper metal layer disposed directly on an upper surface of the lower metal layer and formed of a same material as the first conductive pattern through a same process.

10. The display device of claim 1, further comprising
a capping layer disposed to extend from the display area to the middle area and disposed on the common electrode layer in at least the display area,
wherein the capping layer in the middle area is disposed not to overlap the metal layer in the plan view.

11. The display device of claim 1, wherein
a thickness of the metal layer is about 50 nm or greater.

12. The display device of claim 1, wherein
the metal layer includes at least one selected from molybdenum and titanium.

13. A method of manufacturing a display device, the method comprising:
forming a metal layer on a substrate to have a closed curve shape surrounding a transmissive area in a plan view in a middle area of the substrate, wherein the substrate includes the transmissive area, a display area surrounding the transmissive area, and the middle area between the transmissive area and the display area;
forming a light emitting film on the substrate in at least the display area and at least the middle area;
forming a common electrode layer on the light emitting film in at least the display area and in at least the middle area; and
radiating a laser to the metal layer to remove a portion of each of the light emitting film and the common electrode layer disposed to overlap the metal layer.

14. The method of manufacturing the display device of claim 13, wherein
in the radiating the laser, the metal layer is not removed.

15. The method of manufacturing the display device of claim 13, wherein
in the irradiating the laser, the laser is radiated to the metal layer at least via the substrate.

16. The method of manufacturing the display device of claim 13, wherein
in the radiating the laser, an average temperature in the light emitting film overlapping the metal layer is about 350° C. or higher.

17. The method of manufacturing the display device of claim 13, wherein
the radiating the laser is performed in a vacuum.

18. The method of manufacturing the display device of claim 13, further comprising
forming, after the radiating the laser, an encapsulation layer including a first inorganic encapsulation layer, an organic encapsulation layer, and a second inorganic encapsulation layer which are sequentially stacked therein in at least the display area and at least the middle area,
wherein the first inorganic encapsulation layer is in direct contact with an entire upper surface of the metal layer.

19. The method of manufacturing the display device of claim 13, further comprising
forming a capping layer on the common electrode layer in at least the display area and in at least the middle area,
wherein in the radiating the laser, the capping layer disposed to overlap the metal layer is further removed.

20. The method of manufacturing the display device of claim 13, wherein
after the radiating the laser, a thickness of the metal layer is about 50 nm or greater.
